(19) United States
(12) Patent Application Publication
(10) Pub. No.: US 2025/0183090 A1
(43) Pub. Date: Jun. 5, 2025

(54) BACKGRIND TAPE ETCHING FOR IMPROVED LASER DICING

(71) Applicant: Texas Instruments Incorporated, Dallas, TX (US)

(72) Inventors: Jezreel Duane Aquino, Baguio City (PH); Jeniffer Aspuria, Baguio City (PH); Jun Bautista, Baguio City (PH)

(21) Appl. No.: 18/524,609

(22) Filed: Nov. 30, 2023

(51) Int. Cl. H01L 21/683; B23K 26/40; B23K 101/40; H01L 21/304; H01L 23/00

(52) U.S. Cl. CPC H01L 21/6836; B23K 26/40; H01L 21/304; H01L 24/81; B23K 2101/40; H01L 2221/68327; H01L 2224/81801; H01L 2924/12042

(57) ABSTRACT

A method of fabricating an electronic device includes attaching a first side of a tape to a first side of a wafer and etching an opposite second side of the tape using a laser. The method includes planarizing an opposite second side of the wafer with the first side of the wafer attached to the first side of the tape, and separating a semiconductor die from the wafer after grinding the second side of the wafer.

### BACKGROUND

Laser dicing is a technique to separate semiconductor dies from a processed wafer. The laser is used to create stealth damage along scribe streets between unit areas of the wafer, which initiate and propagate cracks beneath the wafer surface. Multiple laser scans are often used with the laser beam focused to create preferential fractures at different depths in the wafer material, followed by radially expanding a carrier tape attached to the wafer. The laser energy is controlled based on the desired fracture depth, and the process is tailored to a processed wafer thickness dimension. Laser operation settings for a given stealth damage depth can lead to laser dicing defects and reduce manufacturing yield due to variations in wafer thickness. Such defects may include die unseparation where given die does not separate from a neighboring unit area, or meandering defects where a die crack propagates into an active region of a separated die. Semiconductor wafers are often back ground to remove material from the wafer backside prior to laser dicing and radial expansion, and the back grinding operation sets the wafer thickness before die singulation. During back grinding, the wafer is mounted to a carrier tape, referred to as a back grind tape. The tape is placed on a back grinding chuck fixture and the tape is pulled towards the chuck by vacuum pressure, which can bend or bow the wafer due to thickness variations in the back grind tape, with the wafer edge often bowing downward toward the chuck fixture. The subsequent back grinding creates a planar surface on the back side of the wafer in its bowed position. However, planarizing the wafer back surface creates a wafer profile with thickness variations and terminating the vacuum pressure releases the pressure on the wafer, which resumes its natural orientation with uneven wafer thickness. Subsequent laser dicing can result in laser dicing defects due to the thickness variations in the back ground wafer.

### SUMMARY

In one aspect, an electronic device includes a semiconductor die manufactured by attaching a first side of a tape to a first side of a wafer, using a laser, planarizing an opposite second side of the tape, planarizing an opposite second side of the wafer with the first side of the wafer attached to the first side of the tape, and separating the semiconductor die from the wafer after grinding the second side of the wafer.

In another aspect, a method of fabricating an electronic device includes attaching a first side of a tape to a first side of a wafer, using a laser, planarizing an opposite second side of the tape, planarizing an opposite second side of the wafer with the first side of the wafer attached to the first side of the tape, and separating a semiconductor die from the wafer after grinding the second side of the wafer.

In a further aspect, a method of fabricating an electronic device includes attaching a first side of a tape to a first side of a wafer, etching an opposite second side of the tape, planarizing an opposite second side of the wafer with the first side of the wafer attached to the first side of the tape, and separating a semiconductor die from the wafer after grinding the second side of the wafer.

### BRIEF DESCRIPTION OF THE DRAWINGS

FIG. 1 is a flow diagram showing a method for making an electronic device.

FIG. 2 is a partial sectional side elevation view of a wafer with a starting thickness and top side conductive metal or solder bumps.

FIG. 3 is a partial sectional side elevation view of the wafer undergoing a tape installation process.

FIG. 3A is a full sectional side elevation view of the wafer undergoing the tape installation process.

FIG. 4 is a partial sectional side elevation view of the wafer undergoing an etch process using a laser to remove material from the exposed side of the tape.

FIG. 4A is a full sectional side elevation view of the wafer undergoing the tape etch process.

FIG. 5 is a partial sectional side elevation view of the wafer undergoing an installation process to install the tape on the wafer chuck.

FIG. 5A is a full sectional side elevation view of the wafer undergoing the installation process.

FIG. 6 is a partial sectional side elevation view of the wafer undergoing vacuum start process to hold the tape to the wafer chuck.

FIG. 6A is a full sectional side elevation view of the wafer undergoing the vacuum start process.

FIG. 7 is a partial sectional side elevation view of the wafer undergoing back grind process to remove material from the backside of the wafer.

FIG. 7A is a full sectional side elevation view of the wafer undergoing the back grind process.

FIG. 8 is a sectional side elevation view of the wafer and tape being released from the wafer chuck.

FIG. 9 is a sectional side elevation view of the wafer undergoing a laser dicing process.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

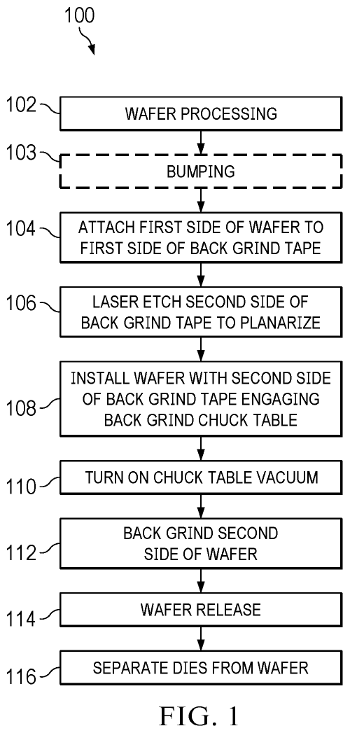

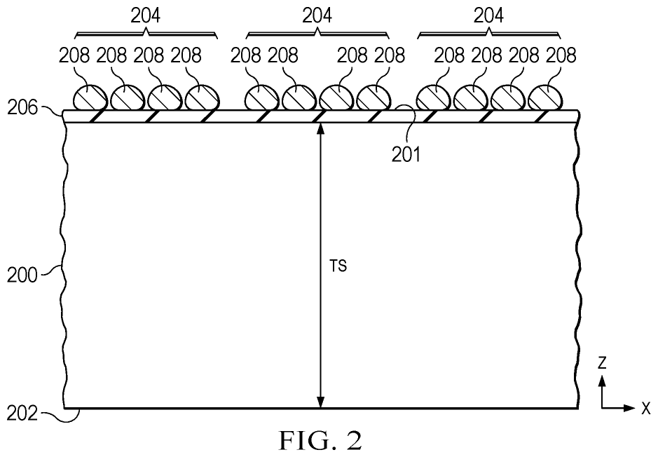

FIG. 1 shows a method 100 for fabricating electronic devices and FIGS. 2-9 show processing of a starting wafer according to the method 100. The method 100 includes back grind tape etching prior to wafer back grinding to mitigate defects during laser dicing for die singulation.

The method 100 begins at 102 with wafer processing, for example, to form one or more electronic components in respective unit areas of a wafer, such as transistors, diodes, resistors, capacitors, etc. (not shown). A starting wafer 200 is illustrated in FIG. 2, such as a silicon wafer, a silicon-on-insulator (SOI), a gallium arsenide (GaN) wafer, etc., with a starting thickness TS. The wafer 200 has a front or first side 201 and a back or second side 202. The wafer 200 in one example has multiple unit areas or die areas 204 that individually correspond to a prospective semiconductor die following die singulation.

In one implementation, the method 100 includes bumping at 103 in FIG. 1 to form conductive metal or solder bumps along a side of a processed wafer. FIG. 2 shows one example, in which conductive metal or solder bumps 208 are formed on conductive die pads (not shown) through openings in an insulator layer 206 on the first side 201 of the processed wafer 200. In another implementation, the bumping at 103 is omitted, for example, for applications in which the subsequently cingulate of semiconductor dies have die pads for wire bonding interconnection.

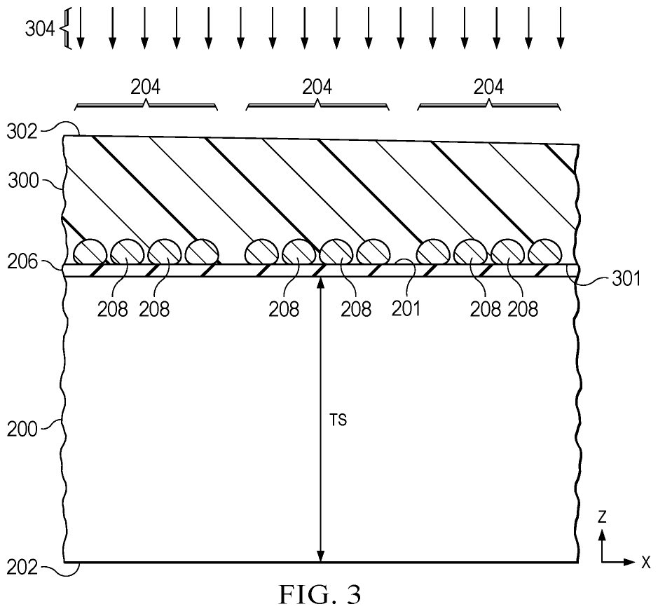

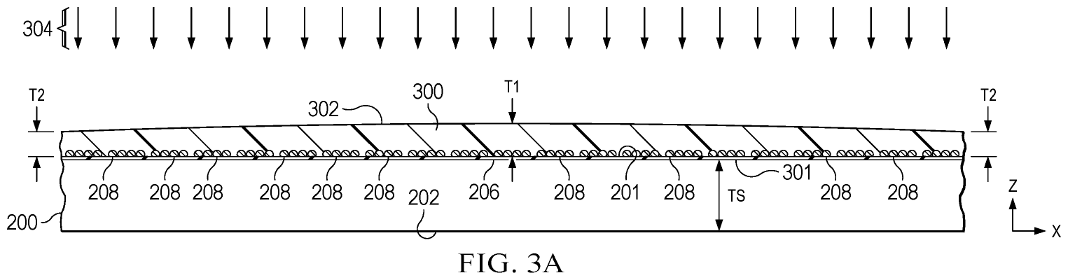

The method 100 includes tape attachment at 104 in FIG. 1. FIGS. 3 and 3A show one example, in which a back grind tape 300 is attached to the first side 201 of the semiconductor die 200 by a tape installation process 304. The installation process 304 can be a manual operation or may be automated. In one example, the process 304 attaches a first side 301 of the tape 300 to the first side 201 of the wafer 200 and includes covering the conductive metal or solder bumps 208 with the tape 300. In one example, the back grind tape 300 is UV curable, and the installation process 304 includes attachment and curing steps.

In this or another example, the back grind tape 300 is MY595 or equivalent tape laminated onto the first side 201 of the wafer 200 in preparation for wafer back grinding and subsequent laser dicing. In these or another example, the tape 300 can include polyester. Polyester based tape can facilitate vaporization during subsequent laser etching for selective removal of material from the second side 302 of the back grind tape 300 in one or more implementations of the method 100.

As shown in FIGS. 3 and 3A, the attached back grind tape 300 has a nonuniform thickness along the third direction Z. As best shown in FIG. 3A, the attached tape 300 has an initial thickness before subsequent etch processing, where the tape thickness between the respective first and second sides 301 and 302 of the tape 300 varies between a first thickness T1 and a smaller second thickness T2. In the illustrated example, the tape thickness at the center of the tape 300 is approximately the first thickness T1 and the thickness at the peripheral edges of the tape 300 is approximately the smaller second thickness T2. The smaller tape thickness T2 at the wafer edges can be due to a variety of causes, for example, edge effects associated with the installation process 304, any included adhesive curing step or steps, tape trimming around the edges of the wafer 200, etc. Other back grind tape thickness variation profiles are possible prior to subsequent tape etching.

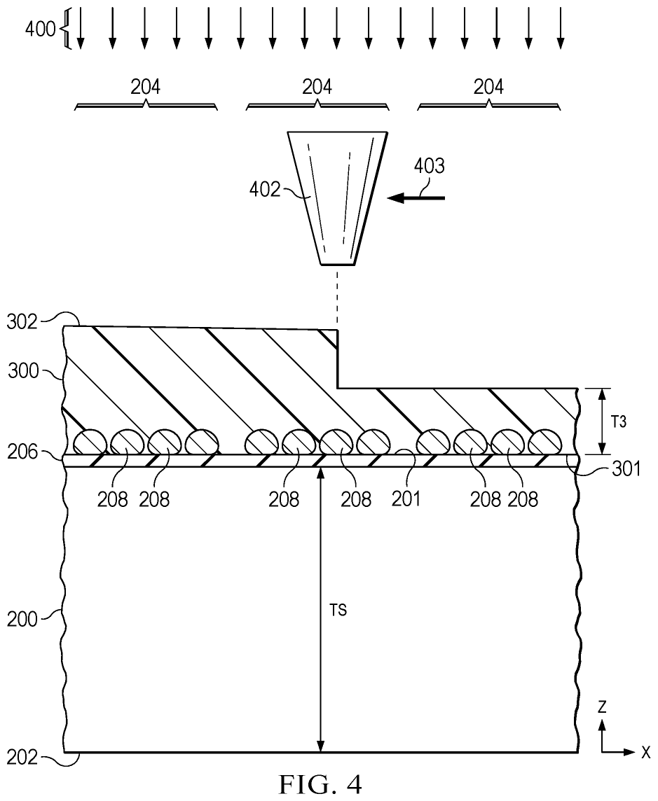

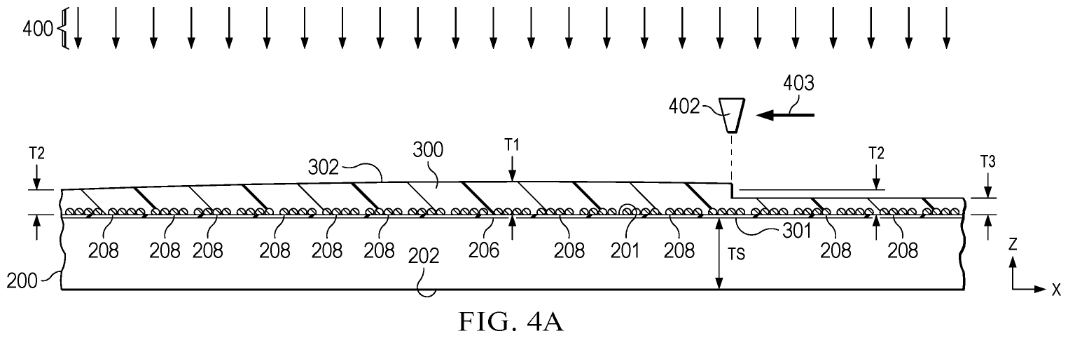

The method 100 continues at 106 in FIG. 1 with back grind tape etching to facilitate background wafer thickness uniformity and subsequent processing steps. FIGS. 4 and 4A a show one example, in which an etch process 400 is performed that removes material from the exposed second side 302 of the back grind tape 300. In one example, the etch process 400 is a laser etch process performed using a laser 402 that is translated along a path shown as arrow 403. The power and positioning of the laser 402 and the etching time of the etch process 400 is controlled in one example according to a desired final or third thickness T3 between the respective first and second sides 301 and 302 of the tape 300. The laser etching in one example extends across the entire exposed second side 302 of the tape 300. In another implementation, the laser etching only etches one or more portions of the second side 302 of the back grind tape 300.

In one example, the etch process 400 provides a clean contactless removal of select amounts of the tape material from all or portions of the second side 302 of the tape 300, including vaporizing at least a portion of the material of the second side 302 of the tape 300 using a laser 402. This provides advantages compared to alternative approaches, such as dissolving using chemicals and/or grinding the tape.

In the illustrated example, the etch process 400 provides a substantially planar etched second side 302 of the tape 300 through a contactless etch process, although not a strict requirement of all possible implementations. Performing the etch process 400 with the laser 402 facilitates removed material vaporization and allows process chamber exhaust to remove the etched material. In contrast, contact techniques such as fly cutting or grinding the exposed side of the tape, for example, using a grinding wheel and a diamond bite to planarize that top surface of the tape, can lead to production downtime in order to clean drains in the interior of a processing chamber. The use of polyester-based tape 300 can also facilitate tape material removal through laser etching. Etch processing provides cost savings and improved throughput in units per hour compared to grinding or fly cutting and eliminates or mitigates downtime from machine conversion to fly cut operations and tool cleaning from clogged drains. Any suitable laser 402 can be used, and the power setting can be adjusted in order to remove a desired amount of tape material to provide a substantially consistent tape thickness T3.

In the illustrated example, the etch process 400 planarizes the second side 302 of the tape 300, although not a strict requirement of all possible implementations. In addition to providing a substantially planar second side 302, the laser etch process 400 in one example provides a substantially uniform thickness T3 of the tape 300. In one example, the laser 402 is a carbon dioxide (CO₂) laser. In another example, the laser 402 is a light-emitting diode (LED) laser.

In the illustrated implementation, the final or third thickness T3 of the etched tape 300 is less than the first thickness T1 and less than the second thickness T2, and the laser etch process 400 removes tape material from all parts of the second side 302 of the tape 300 to provide a planar etched second side 302. In another example, the third thickness T3 is approximately equal to the second thickness T2, and the etch process 400 need not remove tape material from all of the surface of the top side 302, and the third thickness T3 is less than the first thickness T1.

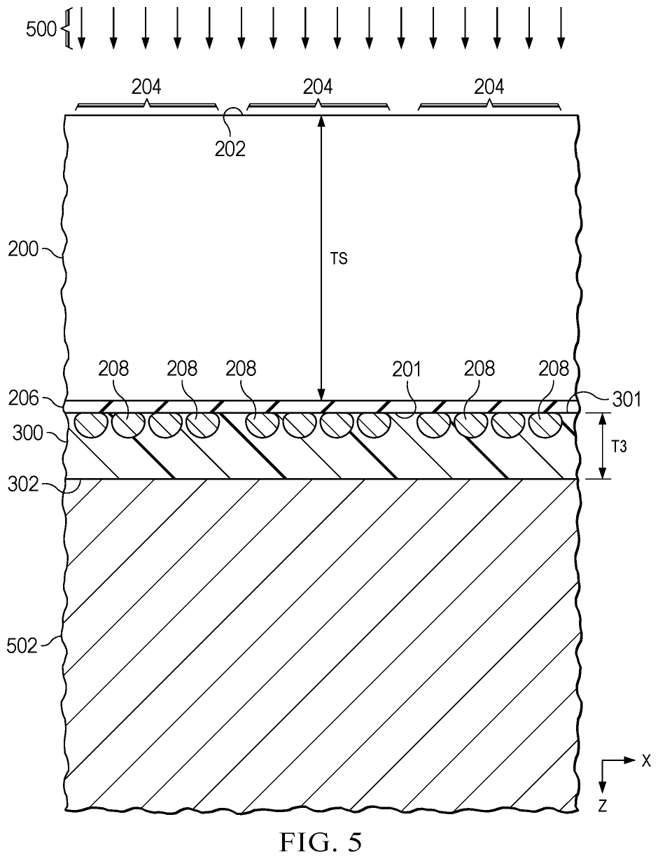

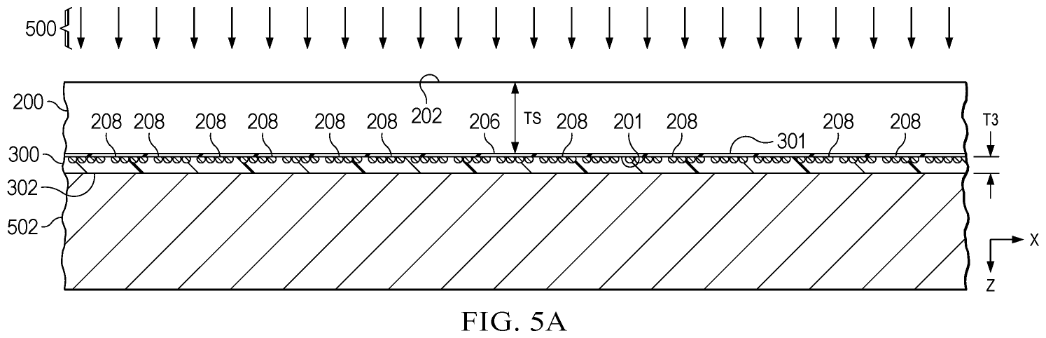

The method 100 continues at 108 in FIG. 1 with wafer installation into a back grind tool. In one example, the wafer is installed at 108 with the planarized second side 302 of the back grind tape 300 engaging a back grind chuck table. FIGS. 5 and 5A a show one example, in which a wafer installation process 500 is performed that installs the wafer on a wafer chuck 502 grinding processing.

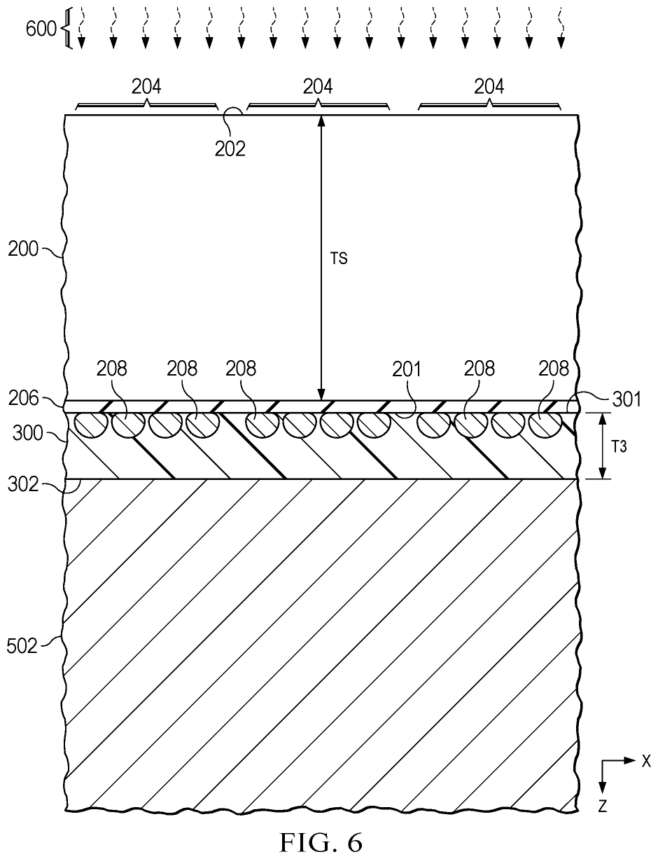

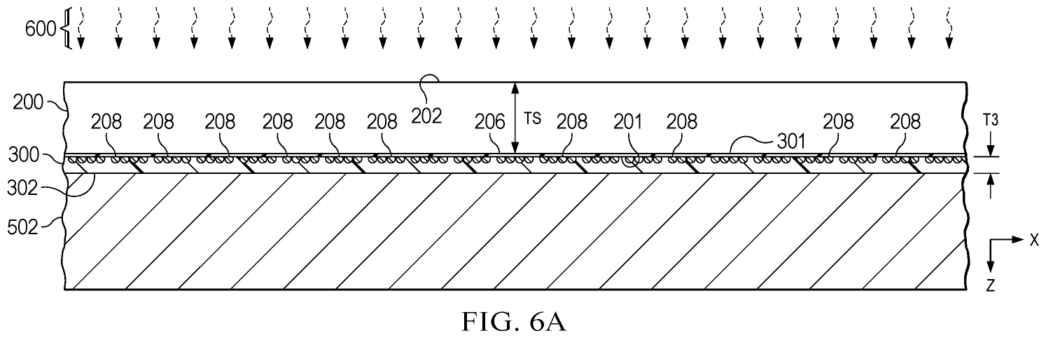

In the illustrated example, a vacuum system of the wafer chuck is turned on at 110 in FIG. 1. FIGS. 6 and 6A show one example, in which a vacuum start process 600 is performed that draws a vacuum to hold the tape 300 to the top side of the wafer chuck 502. The vacuum starting process 600 does not significantly bend or bow the wafer 200 because the back grind tape 300 has a substantially uniform thickness T3.

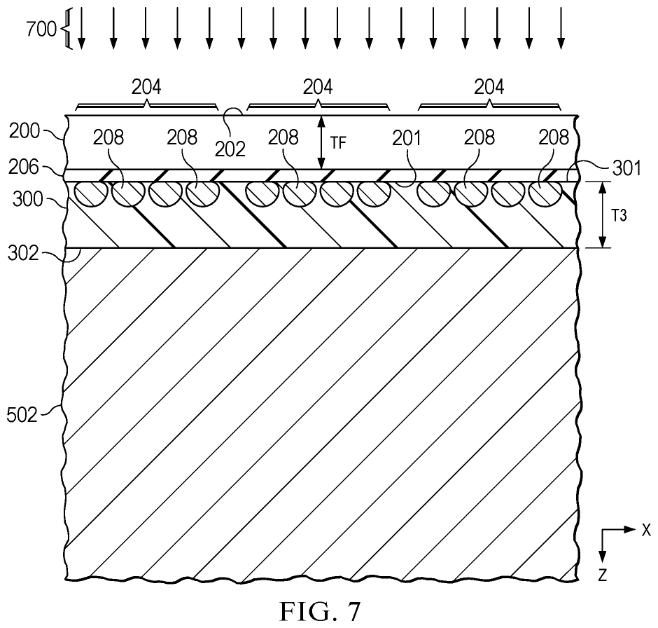

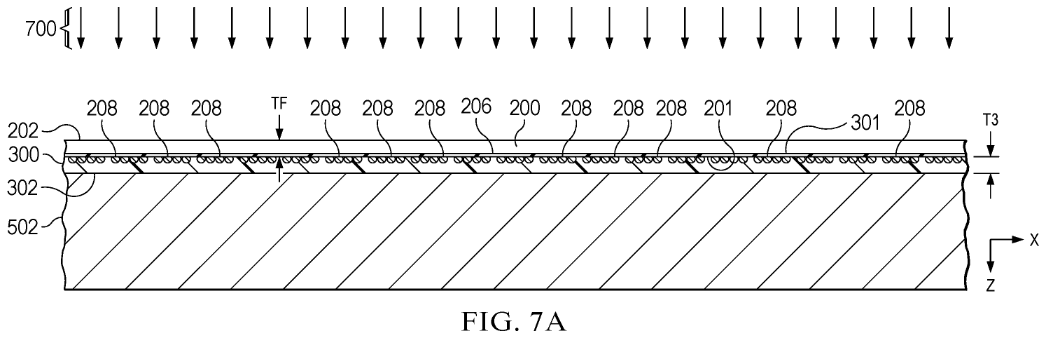

The method 100 continues at 112 in FIG. 1 with planarizing the second side 202 of the wafer 200. FIGS. 7 and 7A a show one example, in which a back grinding process 700 is performed with the first side 201 of the wafer 200 attached to the first side 301 of the tape 300. The back grinding process 700 in the illustrated example remove the material from the second side 202 of the wafer 200, and the process 700 provides a reduced final thickness TF as shown in FIGS. 7 and 7A.

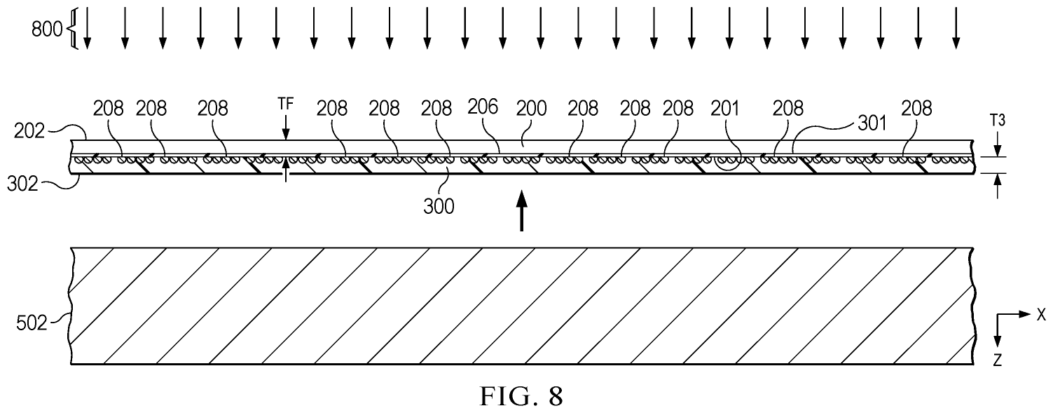

At 114 in FIG. 1, the method 100 continues with wafer release. FIG. 8 shows one example, in which a wafer chuck release process 800 is performed that releases the back ground wafer 200 and the back grind tape 300 from the wafer chuck table 502, including stopping the chuck table vacuum.

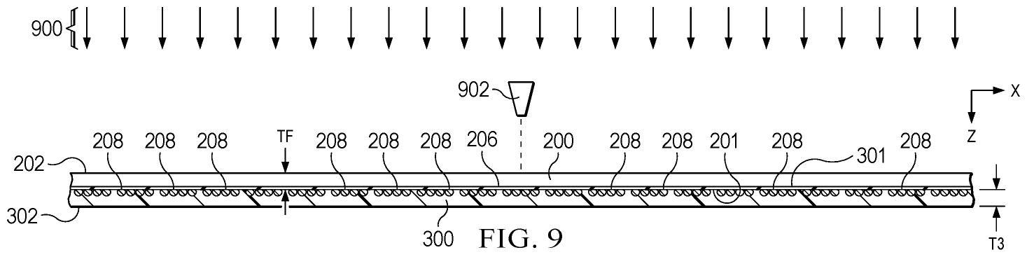

At 116 in FIG. 1, the method 100 in this example includes separating individual semiconductor dies from the processed and back ground wafer 200. FIG. 9 shows one example, in which a laser dicing process 900 is performed using a laser 902 to selectively create stealth damage at a desired depth within the semiconductor wafer 200. The laser dicing process 900 is performed in this example along the back or second side 202 of the semiconductor wafer 200, with the first side 201 of the wafer 200 remaining attached to the first side 301 of the back grind tape 300.

The method can include further processing steps, removing the back grinding tape 300 using known techniques and/or mounting the wafer 200 to a dicing tape (not shown) and radial expansion of the dicing tape to finish the separation of the individual semiconductor dies from the processed wafer 200 (not shown).

Further aspects of the present disclosure provide an electronic device with a semiconductor die manufactured through the above-described processing, for example including attaching a first side 301 of a tape 300 to a first side 201 of a wafer 200, using a laser 402, planarizing an opposite second side 302 of the tape 300, etching and/or planarizing an opposite second side 202 of the wafer 200 with the first side 201 of the wafer 200 attached to the first side 301 of the tape 300, and separating the semiconductor die from the wafer 200 after grinding 112 the second side 202 of the wafer 200.

Modifications are possible in the described examples, and other implementations are possible, within the scope of the claims.

What is claimed is:

1. A method of fabricating an electronic device, the method comprising:
attaching a first side of a tape to a first side of a wafer;
using a laser, planarizing an opposite second side of the tape;
planarizing an opposite second side of the wafer with the first side of the wafer attached to the first side of the tape; and
separating a semiconductor die from the wafer after grinding the second side of the wafer.

2. The method of claim 1, wherein separating the semiconductor die from the wafer includes performing a laser dicing process with the first side of the wafer attached to the first side of the tape.

3. The method of claim 2, wherein the tape includes polyester.

4. The method of claim 3, wherein planarizing the second side of the tape includes vaporizing at least a portion of the material of the second side of the tape using a laser.

5. The method of claim 2, wherein planarizing the second side of the wafer includes grinding the second side of the wafer.

6. The method of claim 2, further comprising forming conductive metal or solder bumps along the first side of the wafer, wherein attaching the first side of the tape to the first side of the wafer includes covering the conductive metal or solder bumps with the tape.

7. The method of claim 1, wherein the tape includes polyester.

8. The method of claim 1, wherein planarizing the second side of the tape includes vaporizing at least a portion of the material of the second side of the tape using a laser.

9. The method of claim 1, wherein planarizing the second side of the tape includes performing a laser etch process using the laser.

10. The method of claim 9, wherein the laser is a carbon dioxide laser.

11. The method of claim 9, wherein the laser is a light-emitting diode laser.

12. The method of claim 9, wherein:
before performing the laser etch process, a thickness between the first and second sides of the tape varies between a first thickness and a smaller second thickness;
the laser etch process removes tape material from the second side of the tape to provide a planar etched second side of the tape with a uniform third thickness between the etched second side of the tape and the first side of the wafer; and
the third thickness is less than the second thickness.

13. The method of claim 12, wherein before performing the laser etch process, the thickness between the first and second sides of the tape at a center of the tape is approximately the first thickness and the thickness between the first and second sides of the tape at a peripheral edge of the tape is approximately the second thickness.

14. The method of claim 9, wherein:
before performing the laser etch process, a thickness between the first and second sides of the tape varies between a first thickness and a smaller second thickness;
the laser etch process removes tape material from at least a portion of the second side of the tape to provide a planar etched second side of the tape with a uniform third thickness between the etched second side of the tape and the first side of the wafer; and
the third thickness is approximately equal to the second thickness.

15. The method of claim 14, wherein before performing the laser etch process, the thickness between the first and second sides of the tape at a center of the tape is approximately the first thickness and the thickness between the first and second sides of the tape at a peripheral edge of the tape is approximately the second thickness.

16. The method of claim 1, wherein:
before planarizing the second side of the tape, a thickness between the first and second sides of the tape varies between a first thickness and a smaller second thickness;
planarizing the second side of the tape removes tape material from at least a portion of the second side of the tape to provide a planar etched second side of the tape with a uniform third thickness between the etched second side of the tape and the first side of the wafer; and
the third thickness is less than the first thickness.

17. An electronic device, comprising a semiconductor die manufactured by:
attaching a first side of a tape to a first side of a wafer;
using a laser, planarizing an opposite second side of the tape;
planarizing an opposite second side of the wafer with the first side of the wafer attached to the first side of the tape; and
separating the semiconductor die from the wafer after grinding the second side of the wafer.

18. The electronic device of claim 17, wherein the semiconductor die includes conductive metal or solder bumps along a side of the semiconductor die.

19. A method of fabricating an electronic device, the method comprising:
attaching a first side of a tape to a first side of a wafer;
etching an opposite second side of the tape;
planarizing an opposite second side of the wafer with the first side of the wafer attached to the first side of the tape; and
separating a semiconductor die from the wafer after grinding the second side of the wafer.

20. The method of claim 19, wherein etching the second side of the tape includes performing a laser etch process.
